(19) United States
(12) Patent Application Publication
(10) Pub. No.: US 2007/0109837 A1
(43) Pub. Date: May 17, 2007

(54) System comprising an electronic device and method of operating a system

(76) Inventors: Ralph Kurt, Eindhoven (NL); Gert Wim 'T Hooft, Eindhoven (NL); Robert Frans Maria Hendriks, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/559,056

(22) PCT Filed: Jun. 2, 2004
(86) PCT No.: PCT/IB04/50825

§ 371 Date: Dec. 1, 2005

(30) Foreign Application Priority Data
Jun. 4, 2003 (EP) 03101627.2

(51) Int. Cl. G11C 11/00

(52) U.S. Cl. 365/156

(57) ABSTRACT

A display device is provided in which the electro-optical effect is created through bending of bendable elements, particularly nanowires or nanotubes. Arrays of bendable elements are provided in areas of the display with the light path. This is possible in that the bendable elements are transparent in the case where they are oriented substantially perpendicular to the substrate, but will absorb light if bent at an angle. Hereto, it is of importance that polarized light is used. The bendable elements are preferably separated from the electrodes through a layer of dielectric material, and are bent under the influence of an electric or magnetic field.

The invention relates to a light modulating system provided with a substrate; bendable elements that are extending from the substrate in a first area, which elements have a bent and an unbent configuration and that are bent under the influence of an electric field and/or a magnetic field, and that are chosen from the group of nanotubes, nanowires and other nanostructures, and provided with means for generating the said electric field and/or a magnetic field.

The invention further relates to a method of operating such a system.

Such a system is known from DE-A 100 59 685. According to the known document, the system is embodied in one device of which the substrate is provided with a light reflective or a light detecting surface. The bending elements, which are carbon nanotubes by preference, are connected to the first electrode through direct attachment. On application of a voltage on the second electrode, which is different from the voltage on the first electrode and in the bendable elements, the bendable elements will bend with their tips towards the second electrode. Therewith, the elements form a coating, which covers at least part of the surface. Hence, there is less reflection or detection, and thus a difference between on and off.

It is a disadvantage of the known device that the field that is needed for bending the elements is relatively large. The large field is the result of the fact that the elements should be bent more or less completely (i.e. from a configuration perpendicular to a direction substantially parallel to the substrate) in order to cover the surface at least partially. The bending at a large angle has the further disadvantage that the mechanical requirement to be set to the elements are very high.

It is thus an object of the invention to provide a system of the kind mentioned in the opening paragraph, in which the requirements regarding bending are less high.

This object is achieved in that the bendable elements are distributed substantially homogeneously in the first area. The term ‘homogeneous’ is understood, in the context of this application, to be a distribution of elements that is sufficiently equal for every portion in the first area. The distribution may be random, uniform or the like. Empty spaces may be present between neighbouring areas, for example if such areas are used as pixels.

The invention is based on the following insights. The first insight is that the elements are transparent, at least to a large extent, if oriented substantially perpendicular to the substrate. It is thus possible to provide bendable elements on the whole surface within the first area. In the prior art, however, the bendable elements are present exclusively on top of the electrodes, and enter the light path only if bent at a substantial angle. They are present outside the light path in their unbent configurations. In contrast, according to the present invention, the bendable elements are present in the area at which radiation falls in any configuration.

The second insight is that the elements absorb radiation even if bent at a small angle only.

The third insight is that the elements are not necessarily part of an electrode, but are provided in the electric and/or magnetic field between the first and the second electrode. The physical principle governing the behavior of the elements is their alignment to the electric and/or magnetic field, so as to obtain an energetically most favorable orientation.

In this manner, the bending of the bendable elements is only needed in so far as to get the elements partially misoriented with reference to the direction of the incoming light. It is thus not necessary to bend them completely, so as to cover a light path next to the elements. The bending angle will generally be between 5-80°, by preference 15-60°, and by further preference 30-45°. The angle is defined in a plane prescribed by the propagation of the polarized light. This is a plane that can be constructed on the basis of the light direction and of the polarization direction. The light direction is preferably substantially identical to the normal to the substrate.

As a consequence of the reduced bending angle, the mechanical requirements are less strict with practical advantages. Not only may the bendable elements be shorter, but also is the adhesion of the elements less problematic. This adhesion is less problematic for at least two reasons: first of all, the bending angle is smaller, secondly the electromagnetic field necessary for bending is smaller, hence a lower pressure is exerted on those elements, and particularly at the interface with the surface which will form a weak part.

It is a first advantage of the system of the invention that it can be miniaturized in comparison with the known device. In the known device, the bendable elements are outside the area of the light path and outside the area of the electrodes, therewith covering area which cannot be used for any other optical purpose. In the system of the present invention, the bendable elements can cover the complete optically suited surface area.

It is a second advantage of the system of the invention that the needed electric and/or magnetic field can be reduced.

It is highly preferred that polarizing means are present. Polarisation of radiation increases the absorption of the radiation in the visible spectrum. Moreover, the bendable elements absorb the radiation anisotropically; and the absorption is dependent on the orientation with respect to the polarization.

In a preferred embodiment of the invention a dielectric layer is present between the bendable elements and the electrodes. In this embodiment, the bending of the bendable elements is based on dipole interaction or on magnetic interaction, depending on the type of bendable elements used. This mechanism of bending is completely different from that of the known mechanism of bending the bendable elements, which is electrostatic bending. For this bending mechanism the elements need to be electrically connected and preferably directly attached to the electrodes. This has the risk of shorts and subsequent current, which make a controlled switching difficult. It further has the risks that the bendable elements are burned away, particularly if those elements consist of organic material, or if for example carbon nanotubes are used. Any conventional inorganic or organic dielectric material such as aluminum oxide, silicon oxide, silicon nitride, a so-called high-K material, can be used. In a further elaboration of this embodiment, the bending is driven by a driving system on the basis of alternating current. This is easier to implement, as no electric field need to be provided.

In a further preferred embodiment, means of addressing the bendable elements pixel by pixel are present. Such addressing means are known per se, and enable to create desired patterns. The resolution of the pixels is only dependent on the size of the electrodes, hence on the resolution desired for the specific application and attainable with lithography (including photolithography, printing and sputtering or other deposition through a mask). Such applications include, without limitation, optical recording systems, lighting systems and display systems.

Particularly preferred is the embodiment wherein the first and second electrodes form a pair of interdigitated electrodes which are capable of switching the bendable elements. This leads to a highly effective provision of the electric field; as the electrodes are interdigitated, a channel is formed between them. The channel width can be small, while at the same time the channel length can be very long.

The electric field strength (V/μm) as required can thus be provided with a lower supply voltage. It is particularly preferred that the first and second electrodes form part of substrate and are provided with a layer of planarizing material so as to create a planar surface on which the bendable elements can be provided. If using interdigitated electrodes, the direction of bending will not be the same at all locations; i.e. there will be bending angles +j and bending angles −j. However, this does not matter for the absorption.

The bendable elements are particularly any nanostructures, such as carbon nanotubes, metallic or semiconductor nanowires and metallic or semiconductor nanotubes or magnetic nanowires or nanotubes filled with any (ferro-)magnetic material. The nanostructures preferably have a diameter—in general smallest lateral dimension—of less than 150 nm, by further preference of less than 50 nm by further preference even between 0.3 and 10 nm. The nanostructures preferably have a length in the range from 5 nm to 10 μm, preferably in the range from 10 to 500 nm and more preferably in the range from 50 to 300 nm. The semiconductor nanowires are preferred as compared to metallic nanowires, as the mutual screening of such nanowires is considerably reduced.

The nanostructures, and particularly the carbon nanotubes may be fictionalized so as to improve their attachment to the substrate surface. This is particularly suitable for carbon nanotubes which can in this manner be attached to a surface of for instance Au, as known from Liu et al., Langmuir, 16(2000), 3569. A suitable fictionalization for an oxide surface (SiO₂, Al₂O₃, glass) is for instance SiCl₃ or Si(OR)₃, with R alkyl, preferably isopropyl or butyl, phenyl. A suitable functionality for a gold surface is a thiol or thiol ether (Z-SH, Z-S—S-Z, Z-CH₂—S—CH₂-Z, with Z the carbon nanotubes). A suitable functionality for a platina surface is a base, such as —OH or —NH₂. A suitable functionality for silver of SiO₂ is an acid, such as —COOH. A suitable functionality for unoxidized silicon is a 1-ethylene-group (—CH═CH₂). A suitable functionality for mica is a phosphite group, or an alkyldiphonic acid (PO₃²⁻).

Nanowires and nanotubes can be provided in an advantageous manner by growing them in a template. The template allows an easy and well controllable definition of the pattern of nanostructures. It is known per se from Schönenberger et al., J. Phys. Chem. B, 101 (1997), 5497-5505. The template is provided with pores that have a diameter preferably in the range from 3 to 200 nm, preferably between 5 and 15 nm. The diameters can be made with conventional technology to have a uniform diameter. The pores may be mutually separated by a distance in the order of 1-10 times the pore diameter. They may be substantially perpendicular to the surface and be laterally ordered by providing suitable conditions or by local surface pretreatment with for instance e-beam or imprinting. The nanowires can be grown by known methods such as electrochemical growth and the VLS (Vapor-Liquid-Solid) Method. Electrochemical growth of the nanowires is possible for III-V materials, II-VI-materials and metals. The VLS-method is for instance suitable for III-V materials and for carbon nanotubes, and is generally achieved at temperatures from 400 to 800° C. It is known per se, for instance from Morales and Lieber, Science, 279(1998), 208-211. The template is at least partially removed after the growth, for instance through wet or dry etching.

However, alternative growth methods are not excluded. The nanowires may further be provided by etching a semiconductor substrate according to a desired pattern. Anodic etching of a semiconductor substrate, particularly a silicon substrate, can be a very suitable method to provide a large number of semiconductor nanowires.

It is furthermore preferred that the nanostructures can be grown such that they comprise an insulating region. This embodiment allows that a separate dielectric layer between the nanostructures and the electrodes is not necessary. Such insulating regions can for instance be realized through the use of the VLS-method and change of the gas composition in the chamber.

In another embodiment, an insulating fluid is present on the substrate, such that the nanostructures are substantially embedded therein. Suitable fluids include liquids, vapors and gases. The fluid is viscous to a certain extent by preference and will then provide a counterforce. This may allow a more proper setting of the bending angle. Another advantage of such a somewhat viscous, insulating fluid is its mechanically stabilizing effect on the pattern of bendable elements. Furthermore, the fluid prevents any sticking of the bendable elements to each other. The material and the viscosity of the fluid can be set according to the skilled person's needs.

In general, the bendable elements will return to their unbent configuration after removal of the electromagnetic field. Next to the use of a fluid for giving a counterforce, the return is influenced by the stiffness of the bendable elements and the adhesion contact. Furthermore, it is possible to reverse the orientation of the electromagnetic field to enable the return to the unbent configuration. In a suitable embodiment, a third electrode is present in a plane parallel to the substrate, but on the other side of the bendable elements. Such a third electrode can provide an electric or magnetic field, leading to the fact that the bendable elements resume their unbent configuration.

The device of the invention can be any opto-electronic device, such as a display, a sensor, an optical recording medium, or reader, an optocoupler, a photodiode, a laserdiode.

As a display, the absorption of the bendable elements results in an electro-optical effect. The display may be designed in different ways, both as a reflective display, but also as a transmissive display. Generally, it will be provided with a plurality of pixels, that can be created by providing the bendable elements in a desired pattern. Furthermore, driving means (such as a driver integrated circuit) and addressing means (such as columns and rows) will be present. The addressing means can be integrated in the substrate. The driving means can be provided on the display by means of assembly, or be processed at the same time. The polarizing means can be both a polarizer, which is particularly suitable for transmissive displays, and a source of polarized light. A polarizer can be applied in combination with a source of polarized light as well, herewith enhancing visibility.

To enhance the visibility of the electro-optical effect, the device comprises or is combined with one or more polarizing layers. The number—typically 1 or 2—, position, orientation of the polarization and type, e.g. circular or linear, reflective or absorbing, of the polarizer to be used depends on the type of display desired. Conveniently, a polarizer may be positioned adjacent the single substrate, either on the side of the bendable elements or the side facing away of the bendable elements. Preferably, a linear polarizer is used.

In the broadest sense, the choice of polarizer material is not essential for the invention and as such any conventional polarizer may be suitably used. For example, the polarizer may be a conventional absorbing polarizer such as a iodine-doped polyvinylacetate foil or a conventional reflective polarizer foil such as the Bragg-reflector laminate disclosed in U.S. Pat. No. 6,025,897, a cholesteric polarizer film disclosed in U.S. Pat. No. 5,506,704. Most of these conventional polarizers are available as ready-to-use foils and may be laminated on the substrate using for example pressure-sensitive optical glue. Moreover, their thickness typically amounts to a few hundred μm. Particularly preferred are polarizer layers obtainable by a wet deposition method, in particular a wet coating or printing method, such as known from WO02/42832.

Depending on the type of the electro-optical effect, the optical performance, such as contrast or viewing angle dependence may be further improved by means of retardation layers. Therefore, a preferred embodiment of the device in accordance with the invention comprises or is combined with one or more retardation layers. Generally, a retardation layer is a transparent, optically anisotropical film, in particular anisotropic in refractive index. Typically, as is known in the art, the retardation layer may be made of a polymer which is anisotropically oriented by means of stretching the film. Thus, a birefringent, uniaxially or biaxially oriented film is obtained. Such a stretch oriented polymer film may be laminated onto a substrate surface using for example pressure-sensitive optical glue. It is particularly preferred that the retardation layer is obtainable by a wet-chemical deposition method. Obviously, the thickness of the retardation layer is to be selected in accordance with the amount of retardation desired, for example, quarter λ, half λ, etc. Generally, the thickness of a retardation layer varies from 0.05 to about 100 μm. In the case of a retardation layer in the form of a stretched polymer foil such as a polycarbonate foil, the thickness is typically 10 to 100 μm, whereas a wet-chemical deposited retardation layer has a typical thickness of 0.05 to 10 μm, or in particular 0.1 to 5.0 μm or more particular 0.2 to 1.0 μm. Suitable retardation layers are known from WO02/42832.

In the embodiment of a transmissive display, it is preferred that the electrodes are transparent. Herewith the substrate can be used as the carrier for the polarizer. Suitable transparent electrically conductive materials are very thin metal layers, and particularly oxidic conductors, such as indium-tin oxide (ITO), ruthenium oxide, leadruthenium oxide (Pb₂Ru₂O₇), strontium lanthane cobalt oxide, rhenium oxide and other materials such as known from EP689249. Transparent electrically conducting organic materials, such as poly-(3,4-ethylenedioxy)thiophene—PEDOT—may be used alternatively.

By far preference, the device is provided with a cover on the side of the bendable elements, such that the bendable elements are present in a cavity. Generally, a spacer is present between the cover and the substrate, which spacer may be part of the cover. Suitable covers are glass plates, glass plates with cavities, for instance formed by powder blasting, plates of inorganic or organic material and the like. Furthermore, use can be made of cover plates that can be bent, so as to contact the substrate at desired areas. The cover is transparent by preference. However, this is not necessary if a light source is present within the cavity and the substrate is transparent.

Gray levels may be generated in the display through the time control of the bending with respect to the illumination scheme. A first option to realize such is that the light source is pulsed or that a scanner is used. A second option is to provide gray levels through control and local variation of the bending angle. Hereto, additional electrodes may be provided. Such additional electrodes are preferably located perpendicular to the first electrodes pair. In case of use of an interdigitated electrodes pair, the one or more additional electrodes are provided either in the substrate or on top of the pattern of bendable elements or both in the substrate and on top of the pattern.

These and other aspects of the invention will be further explained with reference to the Figures in which:

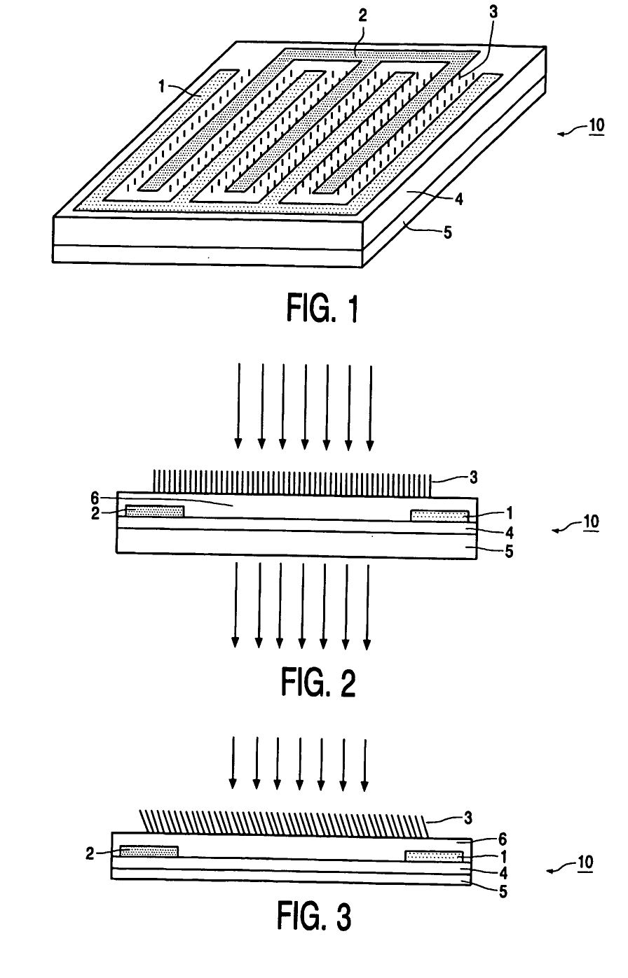

FIG. 1 shows a bird's eye view of the display of the invention;

FIG. 2 shows a diagrammatical cross-section with the bendable elements in their unbent configurations;

FIG. 3 shows a diagrammatical cross-section with the bendable elements in their bent configuration; and

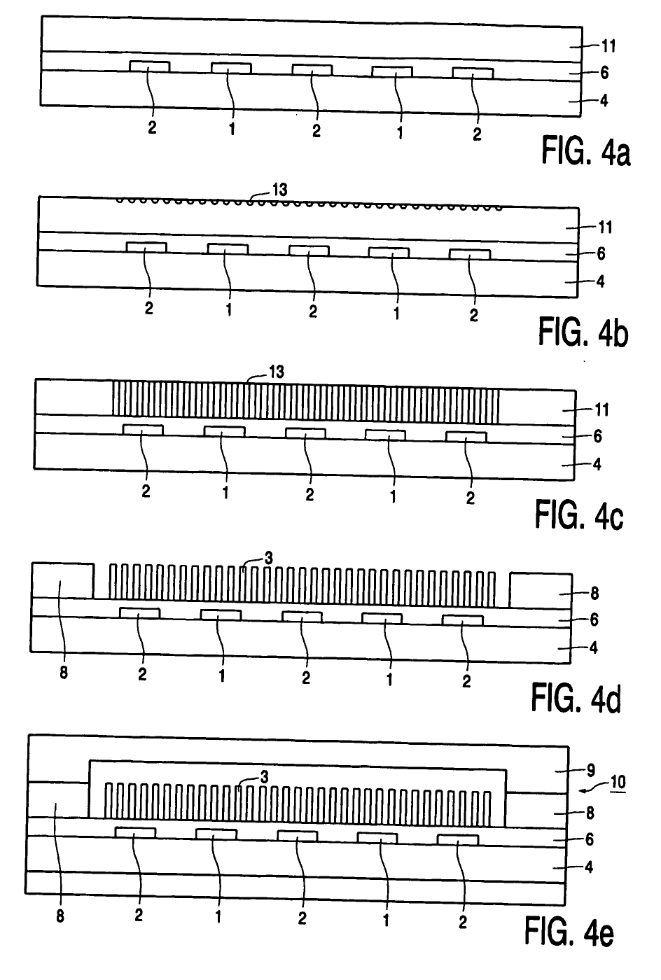

FIGS. 4a-e show diagrammatical cross-sections of several stages in the manufacture of a second embodiment of the display of the invention.

The Figures are not drawn to scale and are purely schematic. Like reference numbers in different Figures refer to like elements.

FIG. 1 gives a schematical representation of a first embodiment of the display of the invention in a bird's eye view. FIGS. 2 and 3 show diagrammatical cross-sections. FIG. 1 shows merely one pixel and any addressing lines are not represented. FIGS. 2 and 3 show a part of a pixel only.

FIG. 1 shows a substrate 4, which is in this case a glass substrate. On its underside, the substrate is provided with a polarizer 5, and on the opposite side with electrodes 1,2 and bendable elements 3. The electrodes 1,2 are interdigitated, the first electrode 1 having four fingers and the second electrode 2 having three fingers. The number of fingers can however be chosen at will, so as to get an optimal channel. The electrodes 1,2 contain indiumtinoxide (ITO).

The cross-section of FIG. 2 shows the layer structure of the display 10 more clearly. In fact, the electrodes 1,2 are covered with a dielectric layer 6 of SiO₂. This dielectric layer is provided by a sol-gel technique, wherein a solution of tetraethoxyorthosilicate is applied and subsequently cured. The dielectric layer 6 has a double function. First of all, it planarizes the substrate 4, which simplifies the application of the bendable elements 3 afterwards. Secondly, it acts as an insulating barrier between the bendable elements 3 and the electrodes 1,2. Therewith, the bendable elements 3 will be influenced by an electric field only, and not by direct electrical contact with the electrodes 1,2. The dielectric layer 6 can be applied by chemical vapor deposition or any other deposition method as well. However, then it is suitable to apply a separate planarization layer. The bendable elements 3 are in this case carbon nanotubes that have been functionalized with Si(OR)₃ groups, wherein R is methyl. Fuctionalization of carbon nanotubes with suitable end groups is known per se from Langmuir, 16(2000), 3569-3573. Herein, single-walled carbon nanotubes of desired length are suspended with ultrasonification in alcohol. Carbon nanotubes have been given carboxylic acid end groups by oxidation. This end group is then substituted through a chemical reaction with Si(OR)₄. In order to achieve a patterned deposition a photoresist material is provided on the substrate, and developed according to a desired pattern. Then, the photoresist material and the substrate are given plasma treatments, so as to make the substrate more hydrophilic and the photoresist more hydrophobic. A suitable treatment is a sequence of an oxygen plasma treatment, a fluor plasma treatment and an oxygen plasma treatment. Bundles of carbon nanotubes will align along the surface, due to the hydrophobic interactions between the individual carbon nanotubes. As an alternative to the use of a photoresist, a mask of another material may be provided, or the nanotubes can be burned away according to the desired pattern. This may be done with a laser bundle of desired intensity.

The resulting display is of the transmissive type, in that a suitable light source of polarized light is provided. Hereto, a glass cover (not shown) is provided around the carbon nanotubes to which the light sources, particularly laser diodes, are attached. The glass cover is provided with cavities according to the desired pattern that have been made with powder blasting in this example. In this case, the picture is provided on the substrate side of the display. Alternatively, the light could come from the other direction. In that case, the image will be viewed from the top side, e.g. through the transparent cover.

If the applied field is zero, the carbon nanotubes are aligned perpendicularly to the light direction, which in this case is also normal to the substrate surface. On application of a field with a field strength in the order of 0.1-5 V/μm the bendable elements will bend to their bent configurations. An alternating current with a frequency between a few Hz and some kHz, preferably about 50 Hz is preferably used.

FIGS. 4e shows a diagrammatical cross-sectional view of a second embodiment of the part of the display of the invention. FIGS. 4a-d show stages in the manufacture thereof. Practically, FIG. 4 shows a view of one pixel with first electrodes 1 and second electrodes 2. These electrodes are interdigitated and each part of the first electrode 1 is connected to the other parts thereof. In this case the bendable elements 3 are semiconductor nanowires that have been grown electrochemically. The bendable elements are provided in a cavity, which is formed by a spacer 8 and a cover 9, the cover being a glass plate.

The bendable elements 3 in this embodiment are provided with template growth, which will be explained with reference to FIGS. 4a-4d. In FIG. 4a the semi-manufactured article is shown after a layered structure of some layers has been provided. The layered structure comprises a substrate 4 of glass, electrodes 1,2 and an etch stop layer 6 of for instance silicon nitride. An aluminum layer 11 is provided on this.

FIG. 4b shows the structure after beginnings of pores 13 have been provided in the aluminum layer 11. This is done with anodized etching of the aluminum, which is therewith converted into alumina (Al₂O₃). The anodized etching of aluminum is done in conventional manner. The pores are extended to the etch stop layer 6 by means of O₂ evolution. The result is an alumina layer with 30% porosity. Half of the pore volume consists of micropores and the other half of the pore volume consists of mesopores 13 with a diameter of 15 nm. The pore density is in the order of 5.10¹⁰/cm². The result is shown in FIG. 4c.

FIG. 4d shows the result after some further steps. First, the mesopores 13 are provided with a thin metal layer as a plating base. Particularly preferred is the provision of a silver layer by wet-chemical deposition of silver sols and subsequent curing, however chemical vapor deposition can be used as an alternative. Thereafter copper rods are provided by preference. It takes place for 100 s at a constant voltage of −0.05 V vs. a standard calomel electrode (SCE) applied by a PAR 273A (EG&G Princeton Applied Research) potentiostat/galvanostat using a 0.01 M CuSO₄ solution (pH between 1 and 2). The length of the copper rods is about 30 nm. An extra electrodeposition step is applied in a 0.01 M H₂SO₄ solution at a constant voltage of −0.2V vs SCE to deposit copper ions, which might still be present in the pores after 100 s deposition. This extra electrodeposition step is desired if afterwards gold is used. Then, the layered structure is provided in a bath with a suitable electrolyte, and the nanowires are grown. Cu nanowires can be grown from CuSO₄, Au nanowires can be grown from K₄Au(CN)₃, Ni nanowires can be grown from NiSO₄/NiCl₂ and CdSe nanowires can be grown from CdCl₂ and H₂SeO₃ in water. In this case Au is used. It was deposited on top of the copper at a constant voltage of −1.00 V vs SCE. A 0.32 M gold(I) cyanide electrolyte solution, containing 0.26 M citric acid and 0.65 M KOH, with a final pH between 5 and 6 is used. The typical current density is about 70 μA cm⁻² membrane area The total membrane area is 0.65 cm². The total pore area (actual deposition area) is estimated to be 10% of this area.

Hereafter the alumina matrix is dissolved at least partially. The alumina matrix is preferably retained for a thickness of a couple of nanometers. This results in an improved adhesion of the nanowires to the substrate. In order to retain the spacers of Al₂O₃, a mask is applied so as to etch selectively. The spacers of Al₂O₃ are porous, but are sufficiently strong to be used as sidewalls. The porous channels can, however, be filled with the nanowire material, so as to improve their strength and impermeability to gas and moisture.

Finally, a cover 9 is positioned on top of the spacer 8 and attached with a glass frit. Thereafter, the polarizer 5 is applied on the back side. If desired the cover 9 may be provided with an electrode layer on one of its faces, preferably the face directed towards the bendable elements. Another electrode may be provided as part of the substrate. Furthermore, the cavity of the bendable elements 3 may be filled with a liquid.

Alternative possibilities for the provision of the nanowires with template growth are possible as well. Particularly, a layer of a precious metal such as Pt or Au can be provided on top of the silicon nitride layer. Such a layer will act as an etch stop and it can be used as plating base at the same time. The layer of the precious metal can be structured according to a desired pattern, and in the end be used as an additional electrode. In such a case, the layer of precious metal may be provided in the regions between the electrodes 1,2. Therewith, the bendable elements 3 then do not extend on top of the electrodes 1,2.

Alternatively, the layer of the precious metal, or any other metal such as Ni, Cu, may be removed after provision of the nanowires and after the dissolution of the alumina matrix. This is particularly suitable, if the nanowires comprise a semiconductor material (provided electrochemically or with the VLS-method). The layer of the precious metal can then be etched selectively with respect to the nanowires, i.e. the nanowires act as a resist mask for the etching. The mechanical stability of the nanowires is not a problem, as for the application as bendable elements a certain mechanical stability is required anyway.

In a further embodiment the electrodes 1,2 are provided on the opposite side, and the precious metal may be provided directly on top of the glass. The opposite side may be the inner side of the cover plate. Most preferred is the embodiment wherein use is made of a substrate transfer method. In this method the original substrate is finally removed, and the alumina matrix is dissolved from the substrate side, instead of the top side.

The substrate transfer method comprises the following: after growing of the nanowires and before dissolution of the alumina matrix, a layer of dielectric material and the electrodes are provided on top of the matrix. This can be suitably done with any thin-film processes, including wet-chemical deposition, sputtering and chemical vapor deposition. Also further interconnect layers may be provided, as well as a protective cover layer of for instance glass or a polymer. Then the device is turned upside down and the substrate, the etch stop layer alias plating base and the alumina matrix are removed. The removal of the glass substrate can be achieved in that a UV-releasable glue layer provided between the glass and the etch stop layer is irradiated with actinic irradiation in the UV-spectrum.

In short, a display device is provided in which the electro-optical effect is created through bending of bendable elements, particularly nanowires or nanotubes. Arrays of bendable elements are provided in areas of the display with the light path. This is possible in that the bendable elements are transparent in the case that they are oriented substantially perpendicular to the substrate, but will absorb light if bent at an angle. Hereto, it is of importance that polarized light be used. The bendable elements are preferably separated from the electrodes through a layer of dielectric material, and are bent under the influence of an electric or magnetic field.

1. A light modulating system provided with:
a substrate;
bendable elements that are extending from the substrate in a first area, which elements have a bent and an unbent configuration and that are bent under the influence of an electric field and/or a magnetic field, and that are chosen from the group of nanotubes, nanowires and other nanostructures, and
means for generating the said electric field and/or a magnetic field,
characterized in that the bendable elements are distributed substantially homogeneously on the substrate in the first area.

2. A light modulating system as claimed in claim 1, characterized in that the system is provided with a polarizing means, such that any radiation in the light path is polarized.

3. A system as claimed in claim 1, characterized in that the means for generating the field include first and second electrodes, and that a dielectric layer is present between the bendable elements and the electrodes, which electrodes and which dielectric layer are part of the substrate and positioned with respect to the bendable elements in an overlaying relationship within the first area.

4. A system as claimed in claim 3, characterized in that the first and second electrodes form a pair of interdigitated electrodes capable of switching the bendable elements.

5. A system as claimed in claim 4, characterized in that the bendable elements are nanostructures having a diameter of 1 to 50 nm.

6. A system as claimed in claim 5, characterized in that the nanostructures comprise a semiconductor material.

7. A system as claimed in claim 1, characterized in that a fluid layer of dielectric material is present on the substrate, such that the bendable elements are substantially embedded in the fluid layer.

8. A system as claimed in claim 2, wherein the electronic device is a display and includes the polarizing means.

9. A system as claimed in claim 8, wherein the display is of the transmissive type and the substrate is transparent.

10. A method of operating a system according to claim 1, comprising the step of bending the bendable elements at an angle between 5 and 70 degrees with respect to the unbent configuration, the bending taking place in a plane prescribed by the propagation of the polarized light.

11. A method as claimed in claim 10, characterized in that the bending is achieved through the application of an electric field by means of alternating current.
